(19) United States
(12) Patent Application Publication
(10) Pub. No.: US 2024/0152667 A1
(43) Pub. Date: May 9, 2024

(54) SELECTION DEVICE, COMMUNICATION CONTROL DEVICE, SIMULATION DEVICE, AND RECORDING MEDIUM

(71) Applicant: FANUC CORPORATION, Minamitsuru-gun, Yamanashi (JP)

(72) Inventor: Toshihiro WATANABE, Yamanashi (JP)

(21) Appl. No.: 18/280,082

(22) PCT Filed: Apr. 6, 2021
(86) PCT No.: PCT/JP2021/014671

§ 371 Date: Sep. 1, 2023

(51) Int. Cl. G06F 30/20

(52) U.S. Cl. CPC G06F 30/20

(57) ABSTRACT

A selection device is for selecting, when operation simulation is to be performed, positional data of an observation object to be used. The selection device includes a position acquisition unit that acquires positional data including coordinate values that indicate the position of the observation object, a state acquisition unit that acquires the state of the observation object including an operation command and at least one item of data not based on the operation command, a worst change amount calculation unit that calculates, based on the state of the observation object, a worst change amount in accuracy of operation simulation between the case where the positional data is used for a calculation process relating to the operation simulation and the case where the data is not used, and a selection unit that selects positional data to be used for the operation simulation, based on the calculated worst change amount.

### TECHNICAL FIELD

The present invention relates to a selection device, a communication control device, a simulation device, and a recording medium.

### BACKGROUND ART

A technology has been proposed to collect position data from a control device that controls an industrial machine such as a machine tool or a robot and perform a motion simulation (including interference check) of the industrial machine using the collected position data. See, for example, Patent Document 1.
Patent Document 1: Japanese Patent No. 4221016

### DISCLOSURE OF THE INVENTION

### Problems to be Solved by the Invention

Not using a portion of the collected position data (for example, position data collected while the machine is stopped) in the motion simulation or not transferring a portion of the collected position data to a simulation device that performs the motion simulation does not always affect the accuracy of the simulation, depending on the control state of the industrial machine.

Using more position data in the motion simulation or transferring more position data to the simulation device than necessary, even if not doing so does not reduce the accuracy of the simulation, can be problematic because of the time required for arithmetic processing or transfer processing of the position data.

It is therefore desirable that the number of position data points or the transfer volume of position data to be used in a motion simulation of an industrial machine be dynamically changeable according to the state of the industrial machine.

### Means for Solving the Problems

(1) A selection device according to an aspect of the present disclosure is a selection device for selecting, when a motion simulation of an observation object is performed using position data of the observation object, one or more position data points to be used in the motion simulation, the selection device including: a position acquisition unit configured to acquire position data points including coordinate values indicating positions of the observation object; a state acquisition unit configured to acquire a state of the observation object including at least one of a motion command transmitted from a device that controls the observation object to the observation object or data not based on the motion command for the observation object; a worst-case change amount calculation unit configured to calculate, for each of the position data points, a worst-case change amount in accuracy of the motion simulation that results from either using the position data point or not using the position data point in arithmetic processing related to the motion simulation, based on the state of the observation object; and a selection unit configured to select one or more position data points to be used in the motion simulation based on the worst-case change amount calculated by the worst-case change amount calculation unit.

(2) A communication control device according to another aspect of the present disclosure is a communication control device that communicatively connects to a simulation device for performing a motion simulation of an observation object, the communication control device including: the selection device described in (1); and a transfer volume control unit configured to determine a volume of position data to be transferred to the simulation device based on a result of the selection by the selection unit.

(3) A simulation device according to another aspect of the present disclosure is a simulation device for performing a motion simulation of an observation object, the simulation device including: the selection device described in (1); and a usage volume control unit configured to determine the number of position data points to be used in the motion simulation based on a result of the selection by the selection unit.

(4) A recording medium according to another aspect of the present disclosure is a computer-readable recording medium recording therein a program for causing a computer to function as the following units to select, when a motion simulation of an observation object is performed using position data of the observation object, one or more position data points to be used in the motion simulation: a position acquisition unit configured to acquire position data points including coordinate values indicating positions of the observation object; a state acquisition unit configured to acquire a state of the observation object including at least one of a motion command transmitted from a device that controls the observation object to the observation object or data not based on the motion command for the observation object; a worst-case change amount calculation unit configured to calculate, for each of the position data points, a worst-case change amount in accuracy of the motion simulation that results from either using the position data point or not using the position data point in arithmetic processing related to the motion simulation, based on the state of the observation object; and a selection unit configured to select one or more position data points to be used in the motion simulation based on the worst-case change amount calculated.

### Effects of the Invention

The aspects of the present invention make it possible to dynamically change the number of position data points or the transfer volume of position data to be used in a motion simulation of an industrial machine according to the state of the industrial machine.

### BRIEF DESCRIPTION OF THE DRAWINGS

FIG. 1 is a functional block diagram illustrating an example of a functional configuration of a simulation system according to a first embodiment;

FIG. 2 is a diagram showing an example of position data points to be acquired;

FIG. 3 is a diagram showing an example of position data points in a case where the state of an observation object is linear interpolation on linear axis;

FIG. 4 is a diagram showing the relationship between position data points and a rounding error;

FIG. 5 is a diagram showing an example of linear interpolation on a linear axis in a case where the state of the observation object involves a boundary;

FIG. 6 is a diagram showing an example of position data points in a case where the state of the observation object is curve interpolation on linear axis;

FIG. 7 is a diagram showing an example of calculation of a worst-case change amount in the case where the state of the observation object is curve interpolation on linear axis;

FIG. 8 is a diagram showing an example of a motion of the observation object in a case where rotary axis linear interpolation is performed;

FIG. 9 is a flowchart for describing data communication processing in the simulation system;

FIG. 10 is a flowchart for describing the details of processes in selection processing for the case where the state of the observation object is linear interpolation on linear axis shown in Step S5 in FIG. 9;

FIG. 11 is a flowchart for describing the details of processes in selection processing for the case where the state of the observation object is curve interpolation on linear axis or interpolation on rotary axis shown in Step S6 in FIG. 9;

FIG. 12 is a functional block diagram illustrating an example of a functional configuration of a simulation system according to a second embodiment; and

FIG. 13 is a flowchart for describing arithmetic processing in the simulation system.

### PREFERRED MODE FOR CARRYING OUT THE INVENTION

### First Embodiment

The following describes a configuration of the present embodiment in detail with reference to the drawings. The present embodiment is described using an example in which a tool or a workpiece in an industrial machine is an observation object. It should be noted that the present invention is also applicable to cases where a control device that controls the industrial machine is an observation object.

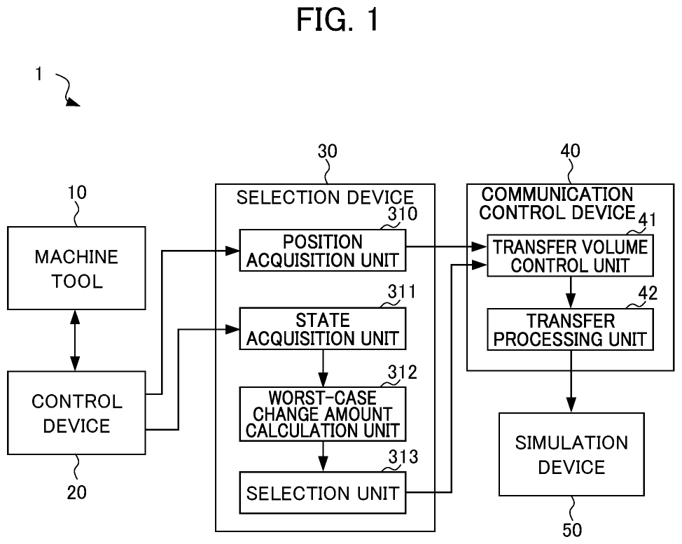

FIG. 1 is a functional block diagram illustrating an example of a functional configuration of a simulation system according to a first embodiment.

As shown in FIG. 1, a simulation system 1 includes a machine tool 10, a control device 20, a selection device 30, a communication control device 40, and a simulation device 50.

The machine tool 10, the control device 20, the selection device 30, the communication control device 40, and the simulation device 50 may be directly connected to each other through connection interfaces, not shown. Alternatively, the machine tool 10, the control device 20, the selection device 30, the communication control device 40, and the simulation device 50 may be connected to each other via a network such as a local area network (LAN). In this case, the machine tool 10, the control device 20, the selection device 30, the communication control device 40, and the simulation device 50 may each have a communication unit, not shown, for communicating with each other through such a connection.

The selection device 30 is described as a separate device from the communication control device 40, but may be incorporated in the communication control device 40 as described below. Furthermore, the selection device 30 and the communication control device 40 may be incorporated in the control device 20.

The machine tool 10 is any of machine tools known to those skilled in the art (for example, five-axis machining center) and performs motions based on motion commands from the control device 20 described below.

The control device 20 is, for example, a numerical control device known to those skilled in the art. The control device 20 generates motion commands based on control information and transmits the generated motion commands to the machine tool 10. By doing so, the control device 20 controls motions of the machine tool 10.

Specifically, the control device 20 controls the machine tool 10 to cause the machine tool 10 to perform a predetermined machining process. The control device 20 is given a machining program describing motions of the machine tool 10. Based on the given machining program, the control device 20 creates motion commands including instructions such as movement instructions for axes and rotation instructions for a motor that drives a spindle, and transmits the motion commands to the machine tool 10 to control motors of the machine tool 10. Thus, the machine tool 10 carries out the predetermined machining process.

In creating a motion command, the control device 20 performs, based on the machining program, linear interpolation or curve interpolation on a linear axis included in the machine tool 10 or performs interpolation on a rotary axis included in the machine tool 10, and generates position data points including coordinate values indicating positions of the observation object for each control cycle. As described below, the control device 20 transmits, along with the motion command, the position data points of the observation object generated for each control cycle and data acquired from the machine tool 10 (for example, motor speed or torque) that is not based on the motion command for the observation object, to the selection device 30.

In a case where the machine tool 10 is, for example, a robot, the control device 20 may be, for example, a robot controller.

The control device 20 is not limited to controlling the machine tool 10 or a robot and may be widely applied to controlling industrial machines in general. Examples of industrial machines include various machines such as machine tools, industrial robots, service robots, forging machines, and injection molding machines. Furthermore, the control device 20 may add, as static information, information such as attributes of each axis in the machine tool 10, which is a place where the observation object is located, indicating whether the axis is a linear axis or a rotary axis.

The present embodiment is described using an example in which the control device 20 is a numerical control device.

The simulation device 50 is, for example, a computer that performs a motion simulation (including interference check) of the machine tool 10 using position data of the observation object such as a tool or a workpiece received via the communication control device 40 described below. It should be noted that the motion simulation can be performed by a known method, and detailed description thereof is omitted.

As shown in FIG. 1, the selection device 30 includes a position acquisition unit 310, a state acquisition unit 311, a worst-case change amount calculation unit 312, and a selection unit 313.

The selection device 30 includes an arithmetic processor, not shown, such as a central processing unit (CPU) to implement operation of the functional blocks shown in FIG. 1. The selection device 30 also includes an auxiliary storage device, not shown, such as read only memory (ROM) or a hard disk drive (HDD) that stores therein various control programs, and a main storage device, not shown, such as random access memory (RAM) for storing data to be temporarily needed for the arithmetic processor to execute the programs.

In the selection device 30, the arithmetic processor reads an OS and application software from the auxiliary storage device, and performs arithmetic processing based on the OS and the application software while deploying the read OS and application software into the main storage device. Based on the results of the arithmetic processing, the selection device 30 controls each piece of hardware. Thus, the functions of the position acquisition unit 310, the state acquisition unit 311, the worst-case change amount calculation unit 312, and the selection unit 313 are implemented. That is, the selection device 30 can be implemented through cooperation of hardware and software.

The position acquisition unit 310 acquires position data points including coordinate values indicating positions of the observation object such as a tool or a workpiece in the machine tool 10 via the control device 20.

Specifically, the position acquisition unit 310 acquires a preset number of position data points at every preset cycle. The first embodiment employs a communication control cycle as the preset cycle and is described using an example in which eight position data points are acquired from the control device 20 per cycle. It should be noted that these settings are merely examples and may be configured to any values.

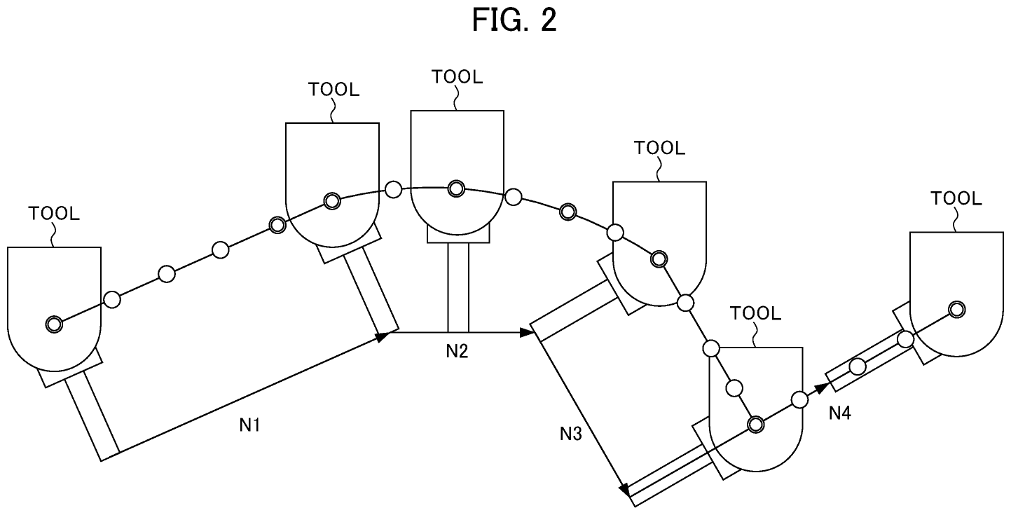

FIG. 2 is a diagram showing an example of position data points to be acquired. It should be noted that FIG. 2 shows an example of sampling of position data to be used in a motion simulation (or interference check) in a configuration in which the machine tool 10 that is controlled by the control device 20 is a five-axis machining center.

As shown in FIG. 2, the path of a tool includes, for example, four path segments N1 to N4 in the machining program. In the path segment N1, linear interpolation on a linear axis of the tool is performed. In the path segment N2, interpolation on a rotary axis of the tool is performed to change the posture of the tool. In the path segment N3, linear interpolation on a linear axis of the tool is performed as in the case of the path segment N1. In the path segment N4, linear interpolation on a linear axis of the tool is performed to retract the tool, and the axis stops at the end point of the segment N4. It should be noted that circles in FIG. 2 indicate interpolated position data points of a center position of the tool, and double circles indicate position data points selected by the selection unit 313 described below.

The state acquisition unit 311 acquires the state of the observation object including at least one of the motion command transmitted from the control device 20 to the observation object or data not based on the motion command for the observation object.

Specifically, as described above, the state acquisition unit 311 acquires, as the state of the observation object, the motion command including instructions indicated by blocks in the machining program such as movement instructions for the axes of the machine tool 10 and rotation instructions for the motor that drives the spindle, along with the added static information. For example, in a configuration in which the machine tool 10 is a five-axis machining center, the machine tool 10 has three linear axes in XYZ axial directions and two rotary axes (rotation/tilt), and the motion command transmitted from the control device 20 to the observation object or the motion command for the observation object includes, for example, “linear axis linear interpolation on”, “linear axis curve interpolation on”, and “rotary axis interpolation on”.

Alternatively or additionally, the state acquisition unit 311 may acquire, as the state of the observation object, data not based on the motion command for the observation object (for example, motor speed or torque). It should be noted that the motor speed and torque, and the position of the observation object change according to the motion command based on the machining program, but can also change due to external force exerted on the observation object from, for example, a device other than the machine tool 10 or a human without being based on the motion command. The state acquisition unit 311 therefore acquires motor speed, motor torque, or position of the observation object as the data not based on the motion command for the observation object.

As a result, the selection device 30 can acquire the state of the observation object in the acquired position data points more accurately.

Based on the state of the observation object, the worst-case change amount calculation unit 312 calculates, for each of the position data points, a worst-case change amount, which indicates the maximum possible change in accuracy of the motion simulation, that results from either using the position data point or not using the position data point in arithmetic processing related to the motion simulation in the simulation device 50.

Hereinafter, operation of the worst-case change amount calculation unit 312 in the following cases of the state of the observation object will be described: (1) linear axis linear interpolation, (2) linear axis curve interpolation or rotary axis interpolation, and (3) axis stop.

(1) Case where State of Observation Object is Linear Interpolation on Linear Axis

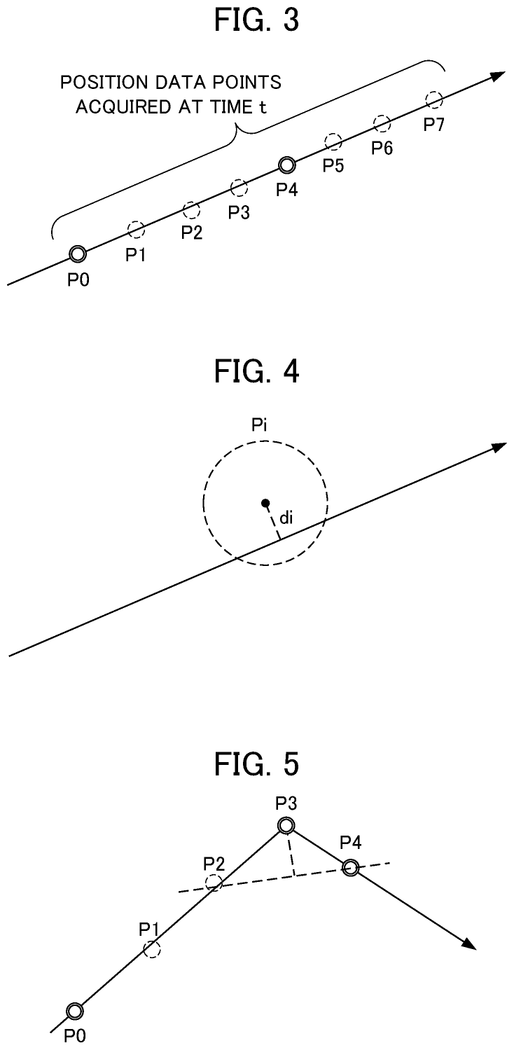

FIG. 3 is a diagram showing an example of position data points in the case where the state of the observation object is linear interpolation on linear axis.

As shown in FIG. 3, the position acquisition unit 310 acquires, from the control device 20, eight position data points (P0 to P7) per communication control cycle. FIG. 4 shows the relationship between the position data points P0 to P7 and the linear interpolation, which is represented by a solid line. A distance di from a position data point Pi to the line of the linear interpolation is approximately (√3)ε(i is a natural number from 0 to 7), where a rounding error in each of the XYZ axial directions of the control device 20 is ±ε.

Accordingly, in the case where the state of the observation object acquired by the state acquisition unit 311 from the control device 20 reflects that linear interpolation (movement command for the machine tool 10) with no bending as shown in FIG. 3 on a linear axis (static information) is on, the worst-case change amount calculation unit 312 calculates the worst-case change amount to be (√3) ε for the position data point Pi.

In a case where a boundary between two or more consecutive motion commands for the observation object is detected from motion commands for the observation object acquired by the state acquisition unit 311 as shown in FIG. 5, the worst-case change amount calculation unit 312 may calculate the worst-case change amount in accuracy of the motion simulation that results from either using the boundary between the motion commands or not using the boundary between the motion commands in the arithmetic processing related to the motion simulation. For example, in a case where there is a bending or a boundary at the position data point P3 as shown in FIG. 5, a distance d3 from the position data point P3 to a straight line connecting the position data points P2 and P4 adjacent thereto is shorter than the length of any side of a triangle P2P3P4 including the three position data points P2, P3, and P4, denoted by d3≤length of side P2P3 and d3≤ length of side P3P4. The relationship between the distance d3 and “D” is, for example, d3≤ D, where “D” is the amount of movement per unit time of the observation object (proportional to movement speed of the observation object) according to the control of the control device 20, because the length of the side P2P3, which is the interval of the linear interpolation, is ≤D and the length of the side P3P4 is also ≤D. Accordingly, the worst-case change amount calculation unit 312 calculates the worst-case change amount to be D for the position data point P3 that is a boundary. It should be noted that D>(√3) ε.

Furthermore, in the case where the state of the observation object is linear interpolation on linear axis, the worst-case change amount calculation unit 312 calculates the worst-case change amount to be “M” for the position data points P0 and P4 to ensure that the first position data point P0 and the middle position data point P4 among the eight position data points P0 to P7 acquired at every communication control cycle are transferred to the simulation device 50 described below. It should be noted that “M” is greater than (√3) ε and has a value that is approximately equal to “D”.

As described above, in the case where the state of the observation object is linear interpolation on linear axis, the worst-case change amount calculation unit 312 calculates the worst-case change amount for each position data point Pi without using the values of the position data points P0 to P7, so that the selection device 30 can dynamically change the transfer volume of position data to be used in the motion simulation without increasing the amount of calculation.

(2) Case where State of Observation Object is Curve Interpolation on Linear Axis or Interpolation on Rotary Axis

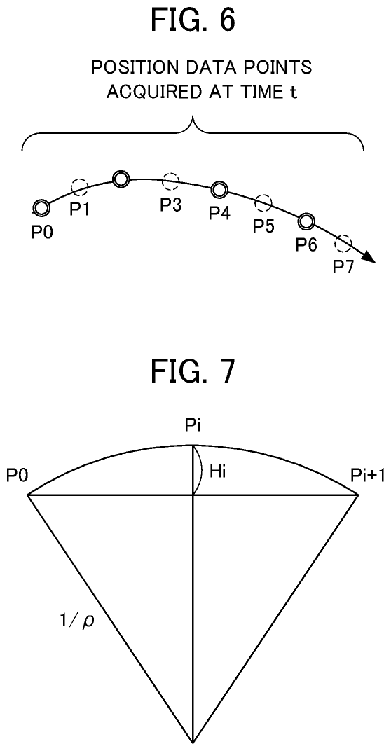

FIG. 6 is a diagram showing an example of position data points in the case where the state of the observation object is curve interpolation on linear axis. It should be noted that while FIG. 6 shows the case where the state of the observation object is curve interpolation on linear axis, the following description also applies to the case where the state of the observation object is interpolation on rotary axis.

As shown in FIG. 6, the position acquisition unit 310 acquires, from the control device 20, eight position data points (P0 to P7) per communication control cycle. In the case where the state of the observation object acquired by the state acquisition unit 311 from the control device 20 reflects that curve interpolation (movement command for the machine tool 10) on a linear axis (static information) is on, for example, the worst-case change amount calculation unit 312 calculates, as the worst-case change amount of a position data point Pi, a length Hi from the position data point Pi to a line segment connecting the position data point P0 and a position data point P(i+1) using the first position data point P0 as a reference as shown in FIG. 7.

Specifically, in the case where the state of the observation object is curve interpolation on linear axis, which in other words is circular interpolation, the position data points P0 to P7 are located on the circumference of a curvature ρ. Accordingly, because the radius of the circle on which the position data points P0 to P7 are located is 1/ρ, the worst-case change amount calculation unit 312 can calculate the length Hi from the position data point Pi as the worst-case change amount of the position data point Pi.

Likewise, using each of the position data points P1 to P6 as a reference, the worst-case change amount calculation unit 312 calculates, as the worst-case change amount, the length Hi from the position data point Pi to the line segment connecting the reference position data point and the position data point P(i+1).

As described above, in the case where the state of the observation object is curve interpolation on linear axis, the worst-case change amount calculation unit 312 calculates the worst-case change amount for each position data point Pi without using the values of the position data points P0 to P7, so that the selection device 30 can dynamically change the transfer volume of position data to be used in the motion simulation without increasing the amount of calculation in the selection device 30 and the communication control device 40.

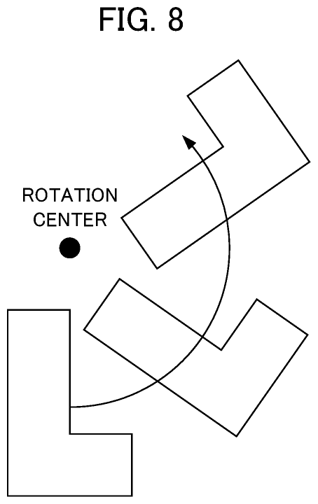

It should be noted that in a case where rotary axis linear interpolation is performed (coordinate values on a rotary axis linearly increases), the observation object (for example, workpiece) performs a circular motion about the rotation center thereof as shown in FIG. 8. Since the observation object moves curvilinearly, rotary axis linear interpolation is treated in the same manner as linear axis curve interpolation. The worst-case change amount calculation unit 312 can therefore calculate the worst-case change amount by the same method as for curve interpolation rather than the method for linear interpolation.

(3) Case where state of observation object reflects axis stop

The position acquisition unit 310 acquires, from the control device 20, eight position data points (P0 to P7) per communication control cycle. In the case where the state of the observation object acquired by the state acquisition unit 311 from the control device 20 reflects that an axis (static information) is stopped (motor speed is “0”), the worst-case change amount calculation unit 312 determines the worst-case change amount in accuracy of the simulation to be “0” for each of the position data points P0 to P7, because no change is expected in accuracy of the simulation even if not all the position data points P0 to P7 are transferred to the simulation device 50.

Based on the worst-case change amount calculated by the worst-case change amount calculation unit 312, the selection unit 313 selects one or more position data points to be used in the motion simulation that is performed by the simulation device 50.

Hereinafter, operation of the selection unit 313 in the following cases of the state of the observation object will be described: (1) linear axis linear interpolation, (2) linear axis curve interpolation or rotary axis interpolation, and (3) axis stop.

(1) Case where State of Observation Object is Linear Interpolation on Linear Axis

In the case where the state of the observation object is linear interpolation on linear axis as shown in FIG. 3, the selection unit 313 selects the first position data point P0 indicated by a double circle from among the eight position data points P0 to P7 in a communication control cycle.

The selection unit 313 also selects a position data point Pi having a worst-case change amount greater than a preset threshold δ among the worst-case change amounts of the position data points P1 to P7. It should be noted that the threshold δ may be set to a value greater than the rounding error, (√3) ε, and smaller than the worst-case change amounts “D” and “M”.

That is, in the case where the state of the observation object is linear interpolation on linear axis that involves no boundary as shown in FIG. 3, the selection unit 313 may select the position data point P4 indicated by a double circle, which is located in the middle among the position data points P1 to P7 and has a worst-case change amount of “M”. In the case where the state of the observation object is linear interpolation on linear axis that involves a boundary as shown in FIG. 4, the selection unit 313 may select the position data point P4, which has a worst-case change amount of “M”, and the position data point P3, which has a worst-case change amount of “D”, from among the position data points P1 to P7.

Thus, with a maximum reduction, the position data to be transferred to the simulation device 50 can be reduced to ¼ without reducing the accuracy of the motion simulation.

(2) Case where State of Observation Object is Curve Interpolation on Linear Axis or Interpolation on Rotary Axis

In the case where the state of the observation object is curve interpolation on linear axis as shown in FIG. 6, the selection unit 313 selects the first position data point P0 indicated by a double circle from among the eight position data points P0 to P7 in a communication control cycle.

The selection unit 313 also selects a position data point Pi having a worst-case change amount greater than the preset threshold based on the worst-case change amount calculated by the worst-case change amount calculation unit 312. For example, in the case shown in FIG. 6, the selection unit 313 may select the position data point P2 having a worst-case change amount greater than the threshold based on the worst-case change amount calculated using the position data point P0 selected first as a reference. The selection unit 313 may select the position data point P4 having a worst-case change amount greater than the threshold based on the worst-case change amount calculated using the position data point P2 selected next as a reference. The selection unit 313 may select the position data point P6 having a worst-case change amount greater than the threshold based on the worst-case change amount calculated using the position data point P4 selected next as a reference.

Thus, with a maximum reduction, the position data to be transferred to the simulation device 50 can be reduced to ½ without reducing the accuracy of the motion simulation.

It should be note that in the case where the state of the observation object is interpolation on rotary axis, the selection unit 313 selects position data points in the same manner as in the case where the state of the observation object is curve interpolation on linear axis.

(3) Case where State of Observation Object Reflects Axis Stop

The selection unit 313 selects only the first position data point P0 because all the position data points have a worst-case change amount of “0”.

Thus, the position data to be transferred to the simulation device 50 can be reduced to ⅛ without reducing the accuracy of the motion simulation.

As shown in FIG. 1, the communication control device 40 includes a transfer volume control unit 41 and a transfer processing unit 42.

The communication control device 40 includes an arithmetic processor, not shown, such as a central processing unit (CPU) to implement operation of the functional blocks shown in FIG. 1. The communication control device 40 also includes an auxiliary storage device, not shown, such as read only memory (ROM) or a hard disk drive (HDD) that stores therein various control programs, and a main storage device, not shown, such as random access memory (RAM) for storing data to be temporarily needed for the arithmetic processor to execute the programs.

In the communication control device 40, the arithmetic processor reads an OS and application software from the auxiliary storage device, and performs arithmetic processing based on the OS and the application software while deploying the read OS and application software into the main storage device. Based on the results of the arithmetic processing, the communication control device 40 controls each piece of hardware. Thus, the functions of the transfer volume control unit 41 and the transfer processing unit 42 are implemented. That is, the communication control device 40 can be implemented through cooperation of hardware and software.

The transfer volume control unit 41 acquires position data points acquired by the position acquisition unit 310 of the selection device 30 at every communication control cycle and the result of the selection by the selection unit 313. Based on the result of the selection, the transfer volume control unit 41 determines the volume of position data to be transferred to the simulation device 50 that performs the motion simulation out of the position data points P0 to P7 acquired at every communication cycle.

The transfer processing unit 42 transfers, to the simulation device 50, the position data in the transfer volume determined by the transfer volume control unit 41.

### <Data Communication Processing in Simulation System 1>

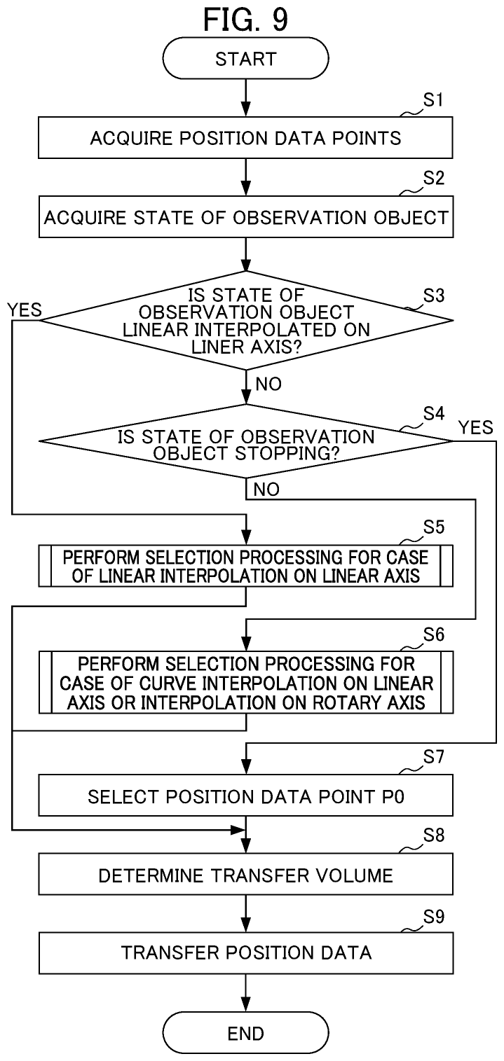

The following describes the flow of data communication processing in the simulation system 1 with reference to FIG. 9.

FIG. 9 is a flowchart for describing the data communication processing in the simulation system 1. The flow shown in FIG. 9 is executed each time position data points are received through the control device 20 at every communication control cycle.

In Step S1, the position acquisition unit 310 of the selection device 30 acquires, via the control device 20, position data points of the observation object such as a tool or a workpiece in the machine tool 10.

In Step S2, the state acquisition unit 311 of the selection device 30 acquires the state of the observation object including at least one of a motion command transmitted from the control device 20 to the observation object or data not based on the motion command for the observation object.

In Step S3, the worst-case change amount calculation unit 312 of the selection device 30 determines whether the state of the observation object acquired in Step S2 is linear interpolation on linear axis. If the state of the observation object is linear interpolation on linear axis, the processing continues to Step S5. If the state of the observation object is not linear interpolation on linear axis, the processing continues to Step S4.

In Step S4, the worst-case change amount calculation unit 312 determines whether or not the state of the observation object acquired in Step S2 is stopping. If the state of the observation object is stopping, the processing continues to Step S7. If the state of the observation object is not stopping, the processing continues to Step S6.

In Step S5, the selection device 30 performs selection processing for the case where the state of the observation object is linear interpolation on linear axis to select position data points to be transferred to the simulation device 50. It should be noted that the detailed flow of the selection processing for the case where the state of the observation object is linear interpolation on linear axis will be described below.

In Step S6, the selection device 30 performs selection processing for the case where the state of the observation object is curve interpolation on linear axis or interpolation on rotary axis to select position data points to be transferred to the simulation device 50. It should be noted that the detailed flow of the selection processing for the case where the state of the observation object is curve interpolation on linear axis or interpolation on rotary axis will be described below.

In Step S7, the worst-case change amount calculation unit 312 determines the worst-case change amount to be “0” for the position data points P0 to P7 acquired in Step S1, because the state of the observation object reflects axis stop, and the selection unit 313 selects only the first position data point P0.

In Step S8, based on the result of the selection in one of Steps S5 to S7, the transfer volume control unit 41 of the communication control device 40 determines the volume of position data to be transferred to the simulation device 50 out of the position data points P0 to P7 acquired in Step S1.

In Step S9, the transfer processing unit 42 of the communication control device 40 transfers, to the simulation device 50, the position data in the transfer volume determined in Step S8.

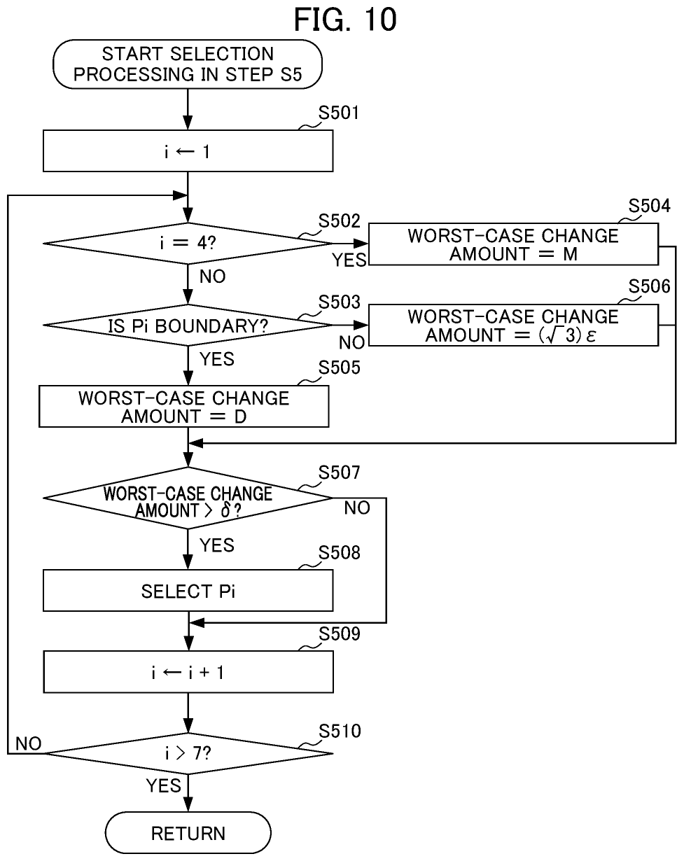

FIG. 10 is a flowchart for describing the details of processes in the selection processing for the case where the state of the observation object is linear interpolation on linear axis shown in Step S5 in FIG. 9. In the flowchart in FIG. 10, Steps S501 to S506 show the flow of processes in the worst-case change amount calculation unit 312, and Steps S507 to S510 show the flow of processes in the selection unit 313.

In Step S501, the worst-case change amount calculation unit 312 initializes the variable number i to “1”.

In Step S502, the worst-case change amount calculation unit 312 determines whether or not the variable number i is “4”. If the variable number i is “4”, the processing continues to Step S504. If the variable number i is not “4”, the processing continues to Step S503.

In Step S503, the worst-case change amount calculation unit 312 determines whether or not the position data point Pi is a boundary. If the position data point Pi is a boundary, the processing continues to Step S505. If the position data point Pi is not a boundary, the processing continues to Step S506.

In Step S504, the worst-case change amount calculation unit 312 determines the worst-case change amount to be “M” for the position data point P4.

In Step S505, the worst-case change amount calculation unit 312 determines the worst-case change amount to be “D” for the position data point Pi that is a boundary.

In Step S506, the worst-case change amount calculation unit 312 determines the worst-case change amount to be (√3)ε for the position data point Pi.

In Step S507, the selection unit 313 determines whether or not the worst-case change amount of the position data point Pi is greater than the threshold δ. If the worst-case change amount of the position data point Pi is greater than the threshold δ, the processing continues to Step S508. If the worst-case change amount of the position data point Pi is equal to or less than the threshold δ, the processing continues to Step S509.

In Step S508, the selection unit 313 selects the position data point Pi having a worst-case change amount greater than the threshold δ as a position data point to be transferred to the simulation device 50.

In Step S509, the selection unit 313 increments the variable number i by “1”.

In Step S510, the selection unit 313 determines whether or not the variable number i is greater than “7”. If the variable number “i” is greater than “7”, the selection processing in Step S5 is terminated, and the simulation system 1 proceeds to Step S8 in FIG. 9. If the variable number i is equal to or less than “7”, the processing returns to Step S502.

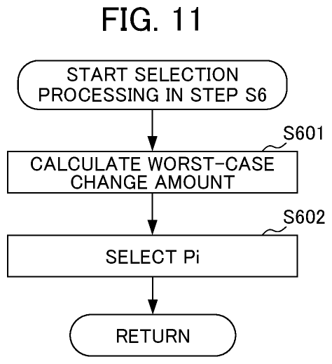

FIG. 11 is a flowchart for describing the details of processes in the selection processing for the case where the state of the observation object is curve interpolation on linear axis or interpolation on rotary axis shown in Step S6 in FIG. 9. In the flowchart in FIG. 11, Step S601 shows a process in the worst-case change amount calculation unit 312, and Step S602 shows a process in the selection unit 313.

In Step S601, using each of the position data points P0 to P6 as a reference, the worst-case change amount calculation unit 312 calculates, as the worst-case change amount of the position data point Pi, the length Hi from the position data point Pi to the line segment connecting the reference position data point and the position data point P(i+1).

In Step S602, the selection unit 313 selects position data points Pi having a worst-case change amount greater than the preset threshold based on the worst-case change amount calculated in Step S601. The selection device 30 then terminates the selection processing in Step S6, and the simulation system 1 proceeds to Step Se in FIG. 9.

As described above, the selection device 30 according to the first embodiment acquires, from the control device 20, not only position data points of the observation object such as a tool or a workpiece in the machine tool 10 but also the state of the observation object. The selection device 30 then calculates the worst-case change amount in accuracy of the simulation to be performed by the simulation device 50 based on the acquired state of the observation object, and selects one or more position data points to be transferred to the simulation device 50 based on the calculated worst-case change amount. This configuration enables the selection device 30 to dynamically change the transfer volume of position data to be used in the motion simulation according to the state of the machine tool 10, thereby achieving an improvement in efficiency of the arithmetic processing related to the motion simulation.

This configuration also enables the communication control device 40 to exclude position data points that are not critical to the accuracy of the simulation, thereby reducing the time required for the position data transfer.

Furthermore, the communication control device 40 allows a decision as to whether to focus on the accuracy of the simulation or the data transfer time to be made automatically, thereby reducing the workload on workers such as a machine tool builder or a machine tool user.

The first embodiment has been described above.

### Modification Example of First Embodiment

In the first embodiment described above, the selection device 30 is a separate device from the communication control device 40. However, the present disclosure is not limited as such. For example, the communication control device 40 may incorporate a selection processing unit that functions as the selection device 30.

This configuration enables the communication control device 40 to dynamically change the transfer volume of position data to be used in the motion simulation according to the state of the machine tool 10, thereby achieving an improvement in efficiency of the arithmetic processing related to the motion simulation.

### SECOND EMBODIMENT

Next, a second embodiment will be described. In the first embodiment, the communication control device 40 determines the volume of position data to be transferred to the simulation device 50 based on the result of the selection by the selection device 30. By contrast, the second embodiment differs from the first embodiment in that a simulation device 50A determines the number of position data points to be used in a motion simulation based on the result of selection by a selection device 30.

This configuration enables the simulation device 50A according to the second embodiment to dynamically change the number of position data points to be used in a motion simulation of an industrial machine according to the state of the industrial machine.

The following describes the second embodiment.

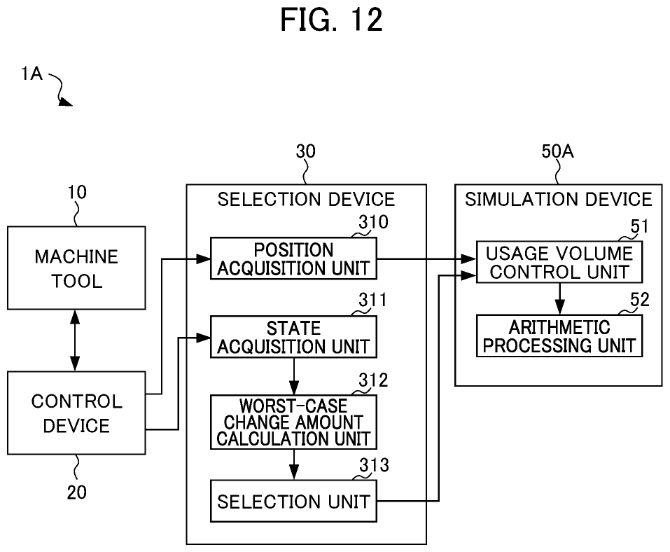

FIG. 12 is a functional block diagram illustrating an example of a functional configuration of a simulation system according to the second embodiment. It should be noted that elements having the same functions as their corresponding elements of the simulation system 1 in FIG. 1 are denoted by the same reference numerals, and detailed description of such elements will be omitted.

As shown in FIG. 12, the simulation system 1A includes a machine tool 10, a control device 20, the selection device 30, and the simulation device 50A.

The machine tool 10, the control device 20, the selection device 30, and the simulation device 50A may be directly connected to each other through connection interfaces, not shown. Alternatively, the machine tool 10, the control device 20, the selection device 30, and the simulation device 50A may be connected to each other via a network such as a local area network (LAN). In this case, the machine tool 10, the control device 20, the selection device 30, and the simulation device 50A may each have a communication unit, not shown, for communicating with each other through such a connection.

It should be note that the selection device 30 is described as a separate device from the simulation device 50A, but may be incorporated in the simulation device 50A as described below. Furthermore, the selection device 30 and the simulation device 50A may be incorporated in the control device 20.

The machine tool 10, the control device 20, and the selection device 30 respectively have the same configurations as the machine tool 10, the control device 20, and the selection device 30 of the first embodiment.

A position acquisition unit 310, a state acquisition unit 311, a worst-case change amount calculation unit 312, and a selection unit 313 of the present embodiment respectively have the same functions as the position acquisition unit 310, the state acquisition unit 311, the worst-case change amount calculation unit 312, and the selection unit 313 of the first embodiment.

In the first embodiment, a communication control cycle is employed as the preset cycle for the position acquisition unit 310, and the number of position data points to be acquired per cycle is set to, for example, eight. In the second embodiment, for example, an arithmetic processing cycle of the simulation device 50A is employed as a preset cycle for the position acquisition unit 310, and the number of position data points to be acquired per cycle is set to, for example, eight. It should be noted that these settings are merely examples and may be configured to any values.

As shown in FIG. 12, the simulation device 50A includes a usage volume control unit 51 and an arithmetic processing unit 52.

The simulation device 50A includes an arithmetic processor, not shown, such as a central processing unit (CPU) to implement operation of the functional blocks shown in FIG. 12. The simulation device 50A also includes an auxiliary storage device, not shown, such as read only memory (ROM) or a hard disk drive (HDD) that stores therein various control programs, and a main storage device, not shown, such as random access memory (RAM) for storing data to be temporarily needed for the arithmetic processor to execute the programs.

In the simulation device 50A, the arithmetic processor reads an OS and application software from the auxiliary storage device, and performs arithmetic processing based on the OS and the application software while deploying the read OS and application software into the main storage device. Based on the results of the arithmetic processing, the simulation device 50A controls each piece of hardware. Thus, the functions of the usage volume control unit 51 and the arithmetic processing unit 52 are implemented. That is, the simulation device 50A can be implemented through cooperation of hardware and software.

The usage volume control unit 51 acquires the position data points acquired at every arithmetic processing cycle by the position acquisition unit 310 of the selection device 30 and the result of the selection by the selection unit 313. Based on the result of the selection, the usage volume control unit 51 determines the number of position data points to be used in the arithmetic processing related to the motion simulation out of the position data points P0 to P7 acquired at every arithmetic processing cycle.

The arithmetic processing unit 52 performs the arithmetic processing related to the motion simulation (including interference check) of the machine tool 10 using the number of position data points determined by the usage volume control unit 51.

<Arithmetic Processing in Simulation System 1A>

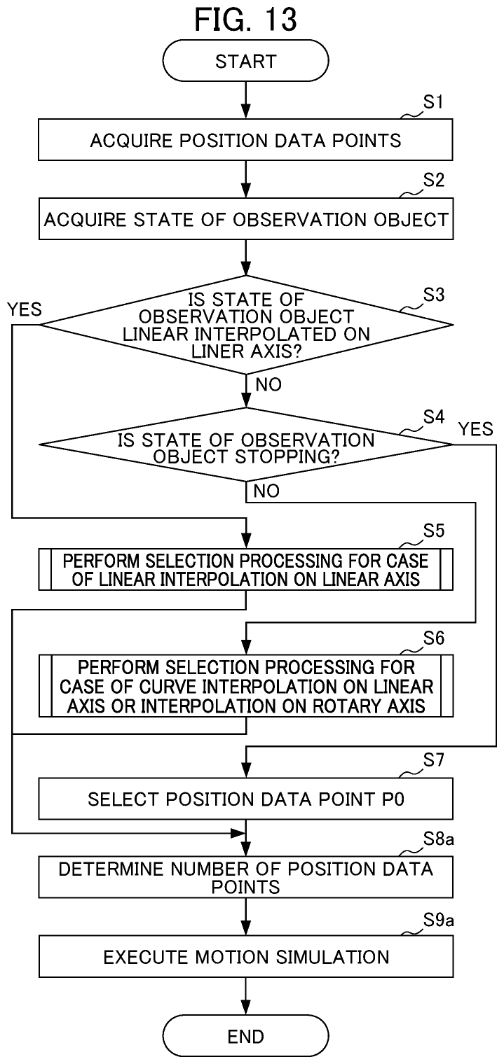

The following describes the flow of the arithmetic processing in the simulation system 1A with reference to FIG. 13.

FIG. 13 is a flowchart for describing the arithmetic processing in the simulation system 1A. The flow shown in FIG. 13 is executed each time position data points are received through the control device 20 at every arithmetic processing cycle.

It should be noted that processes in Steps S1 to S7 are the same as those in Steps S1 to S7 of the first embodiment, and description thereof is omitted.

In Step S8a, based on the result of the selection in one of Steps S5 to S7, the usage volume control unit 51 determines the number of position data points to be used out of the position data points P0 to P7 acquired in Step S1.

In Step S9a, the arithmetic processing unit 52 executes the motion simulation (including interference check) of the machine tool 10 using the number of position data points determined in Step S8a.

As described above, the selection device 30 according to the second embodiment acquires, from the control device 20, not only position data points of the observation object such as a tool or a workpiece in the machine tool 10 but also the state of the observation object. The selection device 30 then calculates the worst-case change amount in accuracy of the simulation based on the acquired state of the observation object, and selects one or more position data points to be used in the motion simulation based on the calculated worst-case change amount. This configuration enables the selection device 30 to dynamically change the number of position data points to be used in the motion simulation according to the state of the machine tool 10, thereby achieving an improvement in efficiency of the arithmetic processing related to the motion simulation.

This configuration also enables the simulation device 50A to exclude position data points that do not affect the accuracy of the simulation, thereby increasing the processing speed of the simulation.

Furthermore, the simulation device 50A allows a decision as to whether to focus on the accuracy of the simulation or the processing speed to be made automatically, thereby reducing the workload on a machine tool builder or a machine tool user.

The second embodiment has been described above.

### Modification Example of Second Embodiment

In the second embodiment described above, the selection device 30 is a separate device from the simulation device 50A. However, the present disclosure is not limited as such. For example, the simulation device 50A may incorporate a selection processing unit that functions as the selection device 30.

This configuration enables the simulation device 50A to dynamically change the number of position data points to be used in the motion simulation according to the state of the machine tool 10, thereby achieving an improvement in efficiency of the arithmetic processing related to the motion simulation.

The first and second embodiments have been described above. The selection device 30 is not limited to the embodiments described above, and encompasses changes such as modifications and improvements to the extent that the object of the present invention is achieved.

### Modification Example 1

In the first and second embodiments, in the case where the state of the observation object is linear interpolation on linear axis, the worst-case change amount calculation unit 312 calculates the worst-case change amount to be “M” for the position data point P4 and the worst-case change amount to be “D” for a position data point Pi that is a boundary. However, the present disclosure is not limited as such. For example, the worst-case change amount calculation unit 312 may calculate the worst-case change amount to be “D” for the position data point P4.

The worst-case change amount calculation unit 312 may also calculate the worst-case change amount to be “M” for any of the position data points P2 to P7 other than the position data point P4.

### Modification Example 2

For another example, in the first embodiment, the selection device 30 and the communication control device 40 are separate devices from the control device 20. However, the present disclosure is not limited as such. For example, the selection device 30 and the communication control device 40 may be incorporated in the control device 20.

### Modification Example 3

For another example, in the second embodiment, the selection device 30 and the simulation device 50A are separate devices from the control device 20. However, the present disclosure is not limited as such. For example, the selection device 30 and the simulation device 50A may be incorporated in the control device 20.

It should be noted that each of the functions included in the selection device 30 according to the first and second embodiments can be implemented by hardware, software, or a combination thereof. Being implemented by software herein means being implemented through a computer reading and executing a program.

The programs can be supplied to the computer by being stored on any of various types of non-transitory computer readable media. The non-transitory computer readable media include various types of tangible storage media. Examples of non-transitory computer readable media include magnetic storage media (such as flexible disks, magnetic tape, and hard disk drives), magneto-optical storage media (such as magneto-optical disks), compact disc read only memory (CD-ROM), compact disc recordable (CD-R), compact disc rewritable (CD-R/W), and semiconductor memory (such as mask ROM, programmable ROM (PROM), erasable PROM (EPROM), flash ROM, and RAM). Alternatively, the programs may be supplied to the computer using any of various types of transitory computer readable media. Examples of transitory computer readable media include electrical signals, optical signals, and electromagnetic waves. Such transitory computer readable media are able to supply the programs to the computer through a wireless communication channel or a wired communication channel such as electrical wires or optical fibers.

It should be noted that writing the programs to be recorded on a storage medium includes processes that are not necessarily performed chronologically and that may be performed in parallel or individually as well as processes that are performed chronologically according to the order thereof.

To put the foregoing into other words, the selection device, the communication control device, the simulation device, and the recording medium according to the present disclosure can take various embodiments having the following configurations.

(1) A selection device 30 according to the present disclosure is a selection device for selecting, when a motion simulation of an observation object is performed using position data of the observation object, one or more position data points to be used in the motion simulation, the selection device including: a position acquisition unit 310 configured to acquire position data points including coordinate values indicating positions of the observation object; a state acquisition unit 311 configured to acquire a state of the observation object including at least one of a motion command transmitted from a control device 20 that controls the observation object to the observation object or data not based on the motion command for the observation object; a worst-case change amount calculation unit 312 configured to calculate, for each of the position data points, a worst-case change amount in accuracy of the motion simulation that results from either using the position data point or not using the position data point in arithmetic processing related to the motion simulation, based on the state of the observation object; and a selection unit 313 configured to select one or more position data points to be used in the motion simulation based on the worst-case change amount calculated by the worst-case change amount calculation unit 312.

This selection device 30 makes it possible to dynamically change the number of position data points or the transfer volume of position data to be used in a motion simulation of an industrial machine according to the state of the industrial machine.

(2) In the selection device 30 described in (1), the state acquisition unit 311 may further detect a boundary between two or more consecutive motion commands for the observation object based on the state of the observation object, the worst-case change amount calculation unit 312 may further calculate the worst-case change amount in accuracy of the motion simulation that results from either using the boundary between the motion commands or not using the boundary between the motion commands in the arithmetic processing related to the motion simulation, and the selection unit 313 may further select a position data point of the observation object at the boundary based on the worst-case change amount calculated by the worst-case change amount calculation unit for the boundary between the motion commands.

This configuration enables the selection device 30 to reliably select a position data point that is a boundary.

(3) In the selection device 30 described in (1) or (2), the state acquisition unit 311 may further acquire static information regarding a place where the observation object is located in addition to the state of the observation object, the worst-case change amount calculation unit 312 may further calculate, for each of the position data points, the worst-case change amount in accuracy of the motion simulation that results from either using the position data point or not using the position data point in the arithmetic processing related to the motion simulation, based on the state of the observation object and the static information, and the selection unit 313 may further select one or more position data points to be used in the motion simulation based on the worst-case change amount in accuracy of the motion simulation calculated by the worst-case change amount calculation unit 312.

This configuration enables the selection device 30 to reliably exclude position data points that do not affect the accuracy of the simulation.

(4) In the selection device 30 described in (3), the static information may include information regarding whether each of axes included in a machine tool 10 where the observation object is located is a linear axis or a rotary axis.

This configuration enables the selection device 30 to exclude position data points that do not affect the accuracy of the simulation more accurately.

(5) In the selection device 30 described in any one of (1) to (4), the data not based on the motion command may include at least one of motor speed, motor torque, or position of the observation object.

This configuration enables the selection device 30 to produce the same effects as the selection device described in any one of (1) to (3).

(6) A communication control device 40 according to the present disclosure is a communication control device that communicatively connects to a simulation device 50 for performing a motion simulation of an observation object, the communication control device including: the selection device 30 described in any one of (1) to (5); and a transfer volume control unit 41 configured to determine a volume of position data to be transferred to the simulation device 50 based on a result of the selection by the selection unit 313.

This communication control device 40 can exclude position data points that do not affect the accuracy of the simulation, thereby reducing the time required for the position data transfer.

(7) A simulation device 50A according to the present disclosure is a simulation device for performing a motion simulation of an observation object, the simulation device including: the selection device 30 described in any one of (1) to (5); and a usage volume control unit 51 configured to determine the number of position data points to be used in the motion simulation based on a result of the selection by the selection unit 313.

This configuration enables the simulation device 50A to exclude position data points that do not affect the accuracy of the simulation, thereby increasing the processing speed of the simulation.

(8) A recording medium according to the present disclosure is a computer-readable recording medium recording therein a program for causing a computer to function as the following units to select, when a motion simulation of an observation object is performed using position data of the observation object, one or more position data points to be used in the motion simulation: a position acquisition unit 310 configured to acquire position data points including coordinate values indicating positions of the observation object; a state acquisition unit 311 configured to acquire a state of the observation object including at least one of a motion command transmitted from a control device 20 that controls the observation object to the observation object or data not based on the motion command for the observation object; a worst-case change amount calculation unit 312 configured to calculate, for each of the position data points, a worst-case change amount in accuracy of the motion simulation that results from either using the position data point or not using the position data point in arithmetic processing related to the motion simulation, based on the state of the observation object; and a selection unit 313 configured to select one or more position data points to be used in the motion simulation based on the worst-case change amount calculated.

This recording medium can produce the same effects as the selection device described in (1).

### EXPLANATION OF REFERENCE NUMERALS

1, 1A: Simulation system
10: Machine tool
20: Control device
30: Selection device
310: Position acquisition unit
311; State acquisition unit
312: Worst-case change amount calculation unit
313: Selection unit
40: Communication control device
41: Transfer volume control unit
42: Transfer processing unit
50, 50A: Simulation device
51: Usage volume control unit
52: Arithmetic processing unit

1. A selection device for selecting, when a motion simulation of an observation object is performed using position data of the observation object, one or more position data points to be used in the motion simulation, the selection device comprising:
a position acquisition unit configured to acquire position data points including coordinate values indicating positions of the observation object;
a state acquisition unit configured to acquire a state of the observation object including at least one of a motion command transmitted from a device that controls the observation object to the observation object or data not based on the motion command for the observation object;
a worst-case change amount calculation unit configured to calculate, for each of the position data points, a worst-case change amount in accuracy of the motion simulation that results from either using the position data point or not using the position data point in arithmetic processing related to the motion simulation, based on the state of the observation object; and
a selection unit configured to select one or more position data points to be used in the motion simulation based on the worst-case change amount calculated by the worst-case change amount calculation unit.

2. The selection device according to claim 1, wherein
the state acquisition unit further detects a boundary between two or more consecutive motion commands for the observation object based on the state of the observation object,
the worst-case change amount calculation unit further calculates the worst-case change amount in accuracy of the motion simulation that results from either using the boundary between the motion commands or not using the boundary between the motion commands in the arithmetic processing related to the motion simulation, and
the selection unit further selects a position data point of the observation object at the boundary based on the worst-case change amount calculated by the worst-case change amount calculation unit for the boundary between the motion commands.

3. The selection device according to claim 1, wherein
the state acquisition unit further acquires static information regarding a place where the observation object is located in addition to the state of the observation object,
the worst-case change amount calculation unit further calculates, for each of the position data points, the worst-case change amount in accuracy of the motion simulation that results from either using the position data point or not using the position data point in the arithmetic processing related to the motion simulation, based on the state of the observation object and the static information, and
the selection unit further selects one or more position data points to be used in the motion simulation based on the worst-case change amount in accuracy of the motion simulation calculated by the worst-case change amount calculation unit.

4. The selection device according to claim 3, wherein
the static information includes information regarding whether each of axes included in an industrial machine where the observation object is located is a linear axis or a rotary axis.

5. The selection device according to claim 1, wherein
the data not based on the motion command includes at least one of motor speed, motor torque, or position of the observation object.

6. A communication control device that communicatively connects to a simulation device for performing a motion simulation of an observation object, the communication control device comprising:
the selection device according to claim 1; and
a transfer volume control unit configured to determine a volume of position data to be transferred to the simulation device based on a result of the selection by the selection unit.

7. A simulation device for performing a motion simulation of an observation object, the simulation device comprising:
the selection device according to claim 1; and
a usage volume control unit configured to determine the number of position data points to be used in the motion simulation based on a result of the selection by the selection unit.

8. A non-transitory computer readable medium encoded with a program for causing a computer to function as the following units to select, when a motion simulation of an observation object is performed using position data of the observation object, one or more position data points to be used in the motion simulation:
a position acquisition unit configured to acquire position data points including coordinate values indicating positions of the observation object;
a state acquisition unit configured to acquire a state of the observation object including at least one of a motion command transmitted from a device that controls the observation object to the observation object or data not based on the motion command for the observation object;
a worst-case change amount calculation unit configured to calculate, for each of the position data points, a worst-case change amount in accuracy of the motion simulation that results from either using the position data point or not using the position data point in arithmetic processing related to the motion simulation, based on the state of the observation object; and
a selection unit configured to select one or more position data points to be used in the motion simulation based on the worst-case change amount calculated.
